(19) United States
(12) Patent Application Publication
(10) Pub. No.: US 2025/0056778 A1
(43) Pub. Date: Feb. 13, 2025

(54) MOUNTING DEVICE AND BENDING DETERMINATION METHOD

(71) Applicant: FUJI CORPORATION, Chiryu (JP)

(72) Inventors: Shota SHIMIZU, Toyota-shi (JP); Toshiaki MIZUNO, Toyota-shi (JP)

(73) Assignee: FUJI CORPORATION, Chiryu (JP)

(21) Appl. No.: 18/718,740

(22) PCT Filed: Dec. 27, 2021
(86) PCT No.: PCT/JP2021/048547

§ 371 Date: Jun. 11, 2024

(51) Int. Cl. H05K 13/04; H05K 13/08

(52) U.S. Cl. CPC H05K 13/0409; H05K 13/041; H05K 13/0812; H05K 13/0813

(57) ABSTRACT

A mounting device, which picks up a component by a suction nozzle attached to a syringe and mounts the component on a board, includes a camera configured to capture an image of a target object from below, a head provided with the syringe to be able to be lifted or lowered and configured to move in a horizontal direction, a control section configured to control the head and the camera such that a jig nozzle is attached to the syringe at a predetermined determination timing and an image of the jig nozzle is captured from below in a state where the syringe is lowered at a predetermined position in the horizontal direction, and a determination section configured to process the captured image and determine bending of the syringe based on a position of the jig nozzle with respect to the predetermined position.

### TECHNICAL FIELD

The present description discloses a mounting device and a bending determination method.

### BACKGROUND ART

Conventionally, there has been proposed a device that captures an image of a nozzle with a camera and processes the image to determine a state of the nozzle. For example, Patent Literature 1 discloses a device that processes an image obtained by capturing an image of a nozzle from a lateral direction, detects a positional deviation amount of a front end of the nozzle, and causes a movement device of the nozzle to correct the positional deviation amount.

### PATENT LITERATURE

Patent Literature 1: JP-A-2000-5679

### SUMMARY OF THE INVENTION

### Technical Problem

In such a device, there is a case where a suction nozzle for mounting components is attached to a lower end of a syringe that can be lifted or lowered and the syringe is bent due to collision or the like during production or maintenance. In the above-described device, although a positional deviation amount of a front end of the nozzle is corrected, determining bending of the syringe is not considered. When the syringe is bent, sliding resistance of the syringe increases, or a suction nozzle influences mounting accuracy of component. When such an influence is detected as a defect in an inspection, bending of the syringe can be checked, but the defect continuously occurs until then, which is not preferable.

A main object of the present disclosure is to appropriately determine bending of a syringe to which a suction nozzle is attached.

### Solution to Problem

The present disclosure employs following members to achieve the main object described above.

A mounting device of the present disclosure, which picks up a component by a suction nozzle attached to a syringe and mounts the component on a board, includes
a camera configured to capture an image of a target object from below,
a head provided with the syringe to be able to be lifted or lowered and configured to move in a horizontal direction,
a control section configured to control the head and the camera such that a jig nozzle is attached to the syringe at a predetermined determination timing and an image of the jig nozzle is captured from below in a state where the syringe is lowered at a predetermined position in the horizontal direction, and
a determination section configured to process a captured image and determine bending of the syringe based on a position of the jig nozzle with respect to the predetermined position.

In a mounting device of the present disclosure, at a predetermined determination timing, an image of a jig nozzle is captured from below in a state where a syringe to which the jig nozzle is attached is lowered at a predetermined position in a horizontal direction, the image is processed, and bending of the syringe is determined based on a position of the jig nozzle with respect to a predetermined position. Accordingly, bending of a syringe can be determined at a predetermined determination timing without waiting for an inspection result or the like of a mounted component. Further, by using a jig nozzle, bending of a syringe can be appropriately determined by excluding influence of bending of a suction nozzle.

### BRIEF DESCRIPTION OF DRAWINGS

FIG. 1 is a configuration diagram schematically illustrating a configuration of component mounting system 10.

FIG. 2 is a configuration diagram schematically illustrating a configuration of mounting device 20.

FIG. 3 is a block diagram illustrating a configuration related to control of mounting device 20 and management device 40.

FIG. 4 is a perspective view illustrating a part of a configuration of head 30.

FIG. 5 is a flowchart illustrating an example of a production process.

FIG. 6 is a flowchart illustrating an example of syringe bending determination processing.

FIG. 7 is a perspective view illustrating an example of a configuration of jig nozzle 36.

FIG. 8 is a diagram illustrating an example of correction values ΔX and ΔY for each rotation angle of each syringe 32.

FIG. 9 is a diagram illustrating an example of distance A.

### DESCRIPTION OF EMBODIMENTS

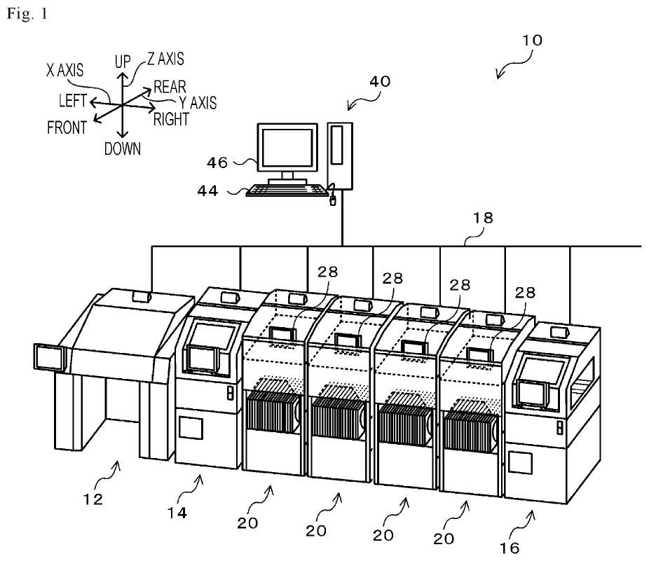

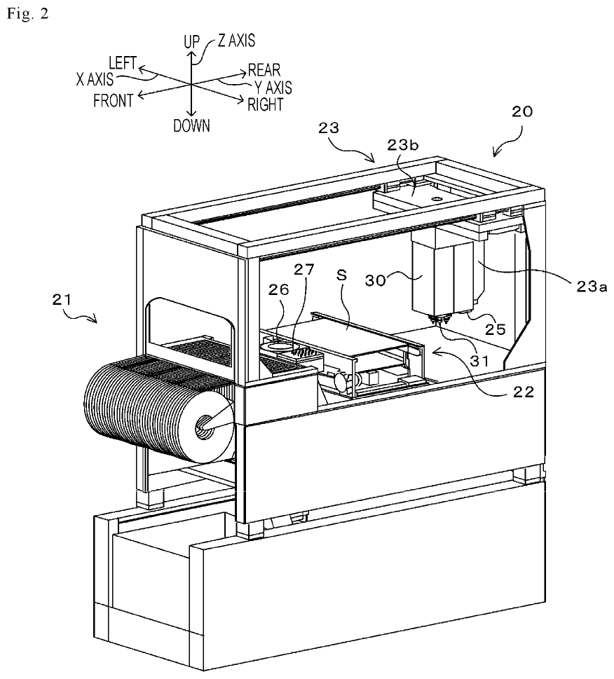

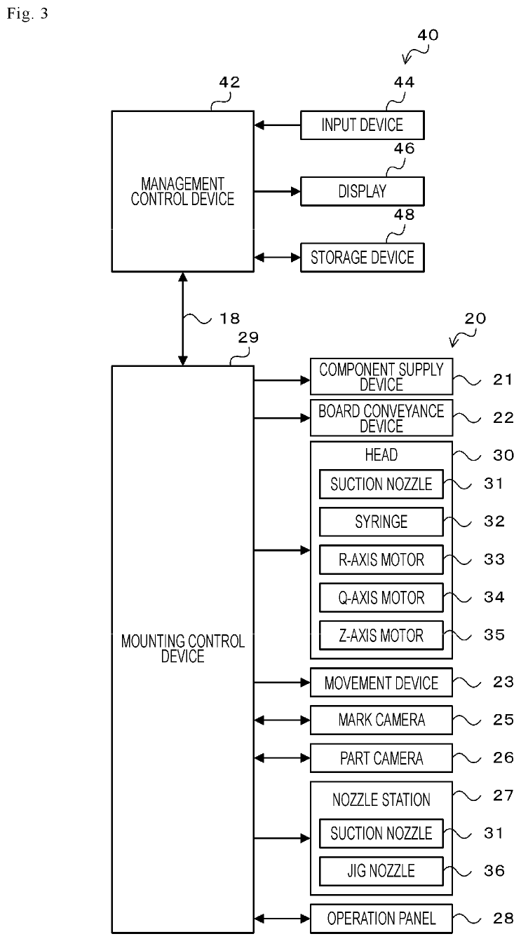

Next, an embodiment of the present disclosure will be described with reference to the drawings. FIG. 1 is a configuration diagram schematically illustrating a configuration of mounting system 10. FIG. 2 is a configuration diagram schematically illustrating a configuration of mounting device 20. FIG. 3 is a block diagram illustrating a configuration related to control of mounting device 20 and management device 40. In FIGS. 1 and 2, a right-left direction is an X direction, a front-rear direction is a Y direction, and an up-down direction is a Z direction.

As illustrated in FIG. 1, mounting system 10 includes print device 12, print inspection device 14, multiple mounting devices 20, mounting inspection device 16, and management device 40, and the devices are connected to LAN 18 that is a network. Print device 12 prints on board S (see FIG. 2) by pushing solder into pattern holes formed in a screen mask. Print inspection device 14 inspects a state of the solder printed by print device 12. Multiple mounting devices 20 are disposed in a conveyance direction (X direction) of board S and mount components on board S. Mounting inspection device 16 inspects mounting states of components mounted on board S by mounting devices 20. Management device 40 manages various types of information and manages entire mounting system 10. Print device 12, print inspection device 14, multiple mounting devices 20, and mounting inspection device 16 are installed side by side in this order in the conveyance direction of board S to form a production line. In addition to the devices, the production line may be provided with a reflow device or the like that performs a reflow process of board S on which a component is mounted, and mounting inspection device 16 may be disposed downstream of the reflow device.

As illustrated in FIG. 2, mounting device 20 includes component supply device 21 that supplies a component, board conveyance device 22 that conveys board S, head 30 that picks up components by using one or multiple suction nozzles 31 and mounts the components on board S, and movement device 23 that moves head 30 in XY directions (horizontal directions). Component supply device 21 is, for example, a tape feeder that supplies components by sending out a tape in which components are accommodated at a predetermined pitch, and multiple component supply devices 21 are set in mounting device 20 such that multiple types of components can be supplied. A tray feeder that supplies components may be set by a tray in which components are accommodated, as component supply device 21. Board conveyance device 22 has conveyor belts provided with a gap therebetween in the front and rear of FIG. 1 and stretched in the right-left direction and conveys board S from left to right in FIG. 2 using the conveyor belts.

Movement device 23 includes Y-axis slider 23b that can move along a guide rail provided in mounting device 20 in the Y direction, and X-axis slider 23a that can move along a guide rail provided on a lower surface of Y-axis slider 23b in the X direction. Head 30 is detachably attached to X-axis slider 23a of movement device 23. Head 30 is removed from X-axis slider 23a, for example, when inspection or maintenance is performed. When head 30 is attached to X-axis slider 23a, head 30 is powered up such that head 30 can operate.

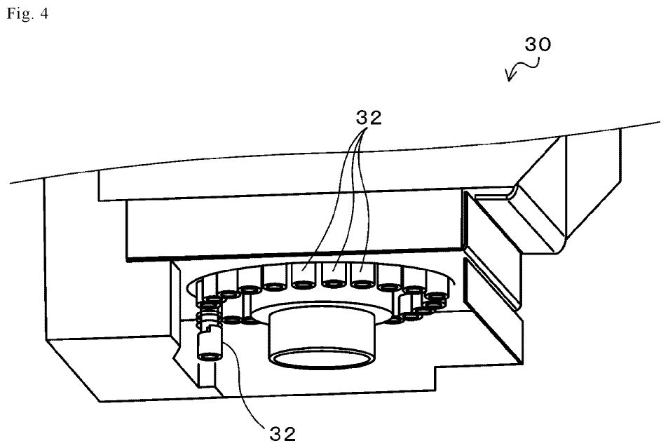

FIG. 4 is a perspective view illustrating a part of a configuration of head 30. As illustrated in FIG. 4, head 30 is configured as a rotary head in which multiple cylindrical syringes 32 respectively holding multiple suction nozzles 31 (not illustrated in FIG. 4) are disposed at predetermined angular intervals in a circumferential direction. Although details of suction nozzle 31 are omitted, suction nozzle 31 picks up a component by a negative pressure supplied from a negative pressure source (not illustrated) to a pickup hole at a front end. Syringe 32 can be detachably attached to a lower end of each suction nozzle 31, and what is suitable for pickup is attached thereto according to a type of a component to be picked up. Further, head 30 includes R-axis motor 33, Q-axis motor 34, and Z-axis motor 35 (see FIG. 3). Head 30 pivots (revolves) each syringe 32 in a circumferential direction around a central axis of head 30 by driving R-axis motor 33. Head 30 pivots (rotates) each syringe 32 (each suction nozzle 31) around a central axis thereof by driving Q-axis motor 34. Further, head 30 lifts and lowers syringe 32 (suction nozzle 31) at a predetermined pivot position (rotational position) in the Z direction by driving Z-axis motor 35.

In addition to this, mounting device 20 includes mark camera 25, part camera 26, nozzle station 27, operation panel 28 (see FIG. 1), mounting control device 29 (see FIG. 3), and the like. Mark camera 25 is attached to head 30 and captures an image of a reference mark, a board ID, and the like affixed to board S, from above. Part camera 26 is installed between component supply device 21 and board conveyance device 22 and captures an image of a target object such as a component picked up by suction nozzle 31 from below. Nozzle station 27 accommodates multiple suction nozzles 31 for replacement and accommodates one or more jig nozzles 36 used for bending determination processing for syringe 32. Operation panel 28 is configured as a touch panel having functions of a display section that displays a screen and an operation section that receives various types of input operations from an operator and displays an operation state and various states of mounting device 20 on a screen.

Mounting control device 29 includes a well-known CPU, ROM, RAM, and the like. Mounting control device 29 outputs drive signals to component supply device 21, board conveyance device 22, head 30, movement device 23, nozzle station 27, and the like. Images from mark camera 25 and part camera 26 are input to mounting control device 29. For example, mounting control device 29 processes an image of board S captured by mark camera 25 to acquire a board ID and recognizes a position of board S by recognizing a reference mark. Further, mounting control device 29 processes an image captured by part camera 26 to determine a pickup posture or the like of a component picked up by suction nozzle 31.

Management device 40 is a general-purpose computer and includes management control device 42, input device 44 such as a keyboard and a mouse, display 46, and storage device 48 such as an HDD or SSD, as illustrated in FIGS. 1 and 3. Management control device 42 includes a well-known CPU, ROM, RAM, and the like, receives an input signal from input device 44, and outputs an image signal to display 46. Storage device 48 stores a production plan of board S. The production plan of board S is a plan that determines which component is mounted at which position on board S in mounting device 20 in which order, how many boards S on which components are mounted are produced, and the like.

Management control device 42 is communicably connected to mounting control device 29 through LAN 18, receives information related to a mounting state from mounting control device 29, and transmits a production instruction such as a job based on the production plan to mounting control device 29. Management control device 42 is communicably connected to respective control devices (not illustrated) of print device 12, print inspection device 14, and mounting inspection device 16 through LAN 18 in addition to this, receives information on a work state from the respective control devices, and transmits work instructions to the respective control devices.

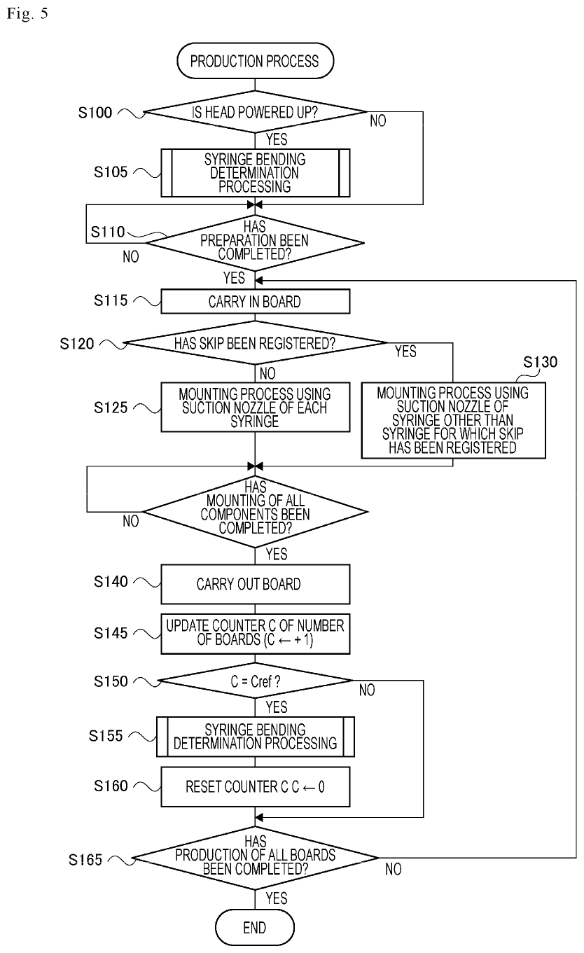

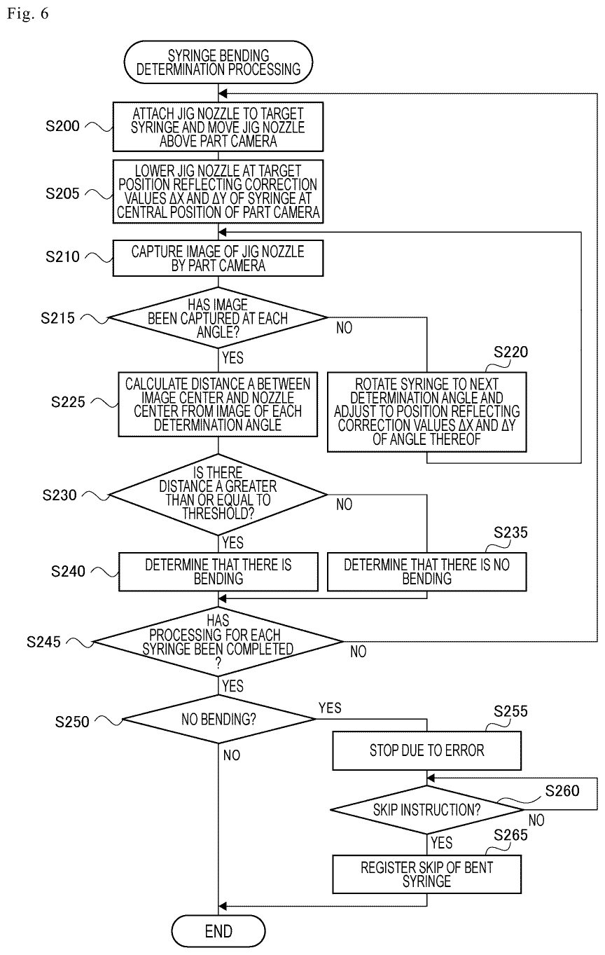

Hereinafter, an operation of mounting device 20 in mounting system 10 configured as described above will be described. FIG. 5 is a flowchart illustrating an example of a production process. This process is performed by mounting control device 29. In the production process, mounting control device 29 first determines whether it is a timing when head 30 is powered up, that is, whether it is a timing when head 30 removed for maintenance or the like is attached to X-axis slider 23a (S100). When mounting control device 29 determines that it is a timing when head 30 is powered up, mounting control device 29 performs syringe bending determination processing (S105) and proceeds to S110. The syringe bending determination processing is performed based on a flowchart of FIG. 6.

In the syringe bending determination process of FIG. 6, mounting control device 29 first attaches jig nozzle 36 to target syringe 32 and moves syringe 32 onto part camera 26 (S200). In S200, it is determined whether there is bending in multiple syringes 32 provided in head 30 as targets in order.

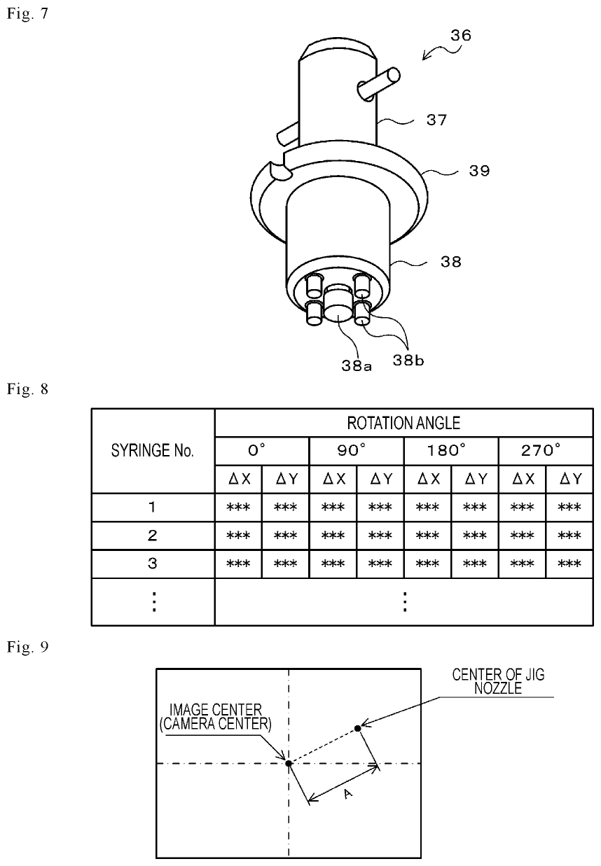

Here, FIG. 7 is a perspective view illustrating an example of a configuration of jig nozzle 36. As illustrated in the drawing, jig nozzle 36 is a nozzle shaped jig member, and base end section 37 inserted into syringe 32, front end section 38 having a larger diameter than base end section 37, and flange section 39 provided between base end section 37 and front end section 38 are coaxially formed. Further, on a lower surface of front end section 38 (front end surface) of jig nozzle 36, first cylindrical section (central cylindrical section) 38a indicating a reference position (axis central position) of jig nozzle 36 is provided at the center, and second cylindrical section 38b having a smaller diameter than a diameter of first cylindrical section 38a is provided concentrically with first cylindrical section 38a. Second cylindrical sections 38b are provided at intervals of 90° so as to divide a concentric circle into four. Accordingly, mounting control device 29 can process an image of a lower surface of jig nozzle 36 captured by part camera 26, thereby detecting a central position of jig nozzle 36 from a position of first cylindrical section 38a in the image. Further, mounting control device 29 can detect a rotation angle of jig nozzle 36 (syringe 32) around an axis from a position of each second cylindrical section 38b in the image. Jig nozzle 36 is accommodated in a state where flange section 39 is supported by an edge of an accommodation section of nozzle station 27.

Next, mounting control device 29 controls head 30 and movement device 23 such that jig nozzle 36 is lowered to a predetermined height position in the Z direction with respect to a central position of part camera 26 with a position reflecting correction values ΔX and ΔY of target syringe 32 as a target position in a horizontal direction (S205). The predetermined height position in the Z direction may be a position within a depth of field of part camera 26, and is, for example, a position slightly higher than a height position when a component is mounted on board S.

FIG. 8 is a diagram illustrating an example of correction values ΔX and ΔY for each rotation angle of each syringe 32. As illustrated, correction value ΔX in the X direction and correction value ΔY in the Y direction are set for each rotation angle (for example, 0°, 90°, 180°, and) 270° of each syringe 32. It is assumed that correction values ΔX and ΔY are set by performing calibration in advance. Mounting control device 29 reads correction values ΔX and ΔY according to a rotation angle of syringe 32 for setting a mounting target component in a predetermined mounting direction, and mounts the component at target positions X+ΔX and Y+ΔY in which correction values ΔX and ΔY are reflected in a mounting position X and Y of a job. In S205, mounting control device 29 reflects correction values ΔX and ΔY of a rotation angle of 0° (reference angle) among respective correction values ΔX and ΔY of target syringe 32.

Subsequently, mounting control device 29 captures an image of jig nozzle 36 from below by part camera 26 (S210) and determines whether the images of jig nozzle 36 have been captured at respective determination angles (rotation angle) (S215). In the present embodiment, the determination angles are four angles of 0°, 90°, 180°, and 270°. When it is determined that the images have not been captured at the respective determination angles, mounting control device 29 rotates syringe 32 to the next determination angle and adjusts a position of syringe 32 in the horizontal direction to a position reflecting correction values ΔX and ΔY of the next determination angle (S220). Then, mounting control device 29 returns to S210 and captures an image of jig nozzle 36. In S220, mounting control device 29 may perform position adjustment and re-lowering of syringe 32 in the horizontal direction after lifting syringe 32 once or may perform the position adjustment in the horizontal direction without lifting and lowering syringe 32.

When it is determined in S215 that the images of jig nozzle 36 have been captured at the respective determination angles, mounting control device 29 processes images of the respective determination angles, calculates distance A between a central position of the image and a central position of jig nozzle 36 (S225, see FIG. 9), and determines whether there is distance A greater than or equal to a threshold (S230). The central position of jig nozzle 36 can be detected from a position of first cylindrical section 38a (omitted in FIG. 9) in the image as described above. When it is determined that all of distances A of respective determination images are less than the threshold, mounting control device 29 determines that target syringe 32 is not bent (S235). Meanwhile, when it is determined that any one of distances A of the respective determination images is greater than or equal to the threshold, mounting control device 29 determines that target syringe 32 is bent (S240).

Then, mounting control device 29 determines whether the processing for each syringe 32 has been completed (S245), and when it is determined that the processing has not been completed, the processing returns to S200 to perform the processing. That is, mounting control device 29 repeats the processing of subsequently attaching jig nozzle 36 to each syringe 32, capturing an image by part camera 26, and determining the presence or absence of bending. When it is determined that the processing has been completed in S245, mounting control device 29 determines whether each syringe 32 processed this time is not bent (S250), and when it is determined that each syringe 32 is not bent, the syringe bending determination processing ends.

Meanwhile, when it is determined that there is bending in any syringe 32, mounting control device 29 stops mounting device 20 due to the error (S255). When stop is performed due to the error, mounting control device 29 transmits an indication of stop due to error to management device 40 or displays the indication on operation panel 28. Mounting control device 29 turns on a warning lamp of mounting device 20. Operation panel 28 displays the fact that a bending error of syringe 32 occurs, the fact that the mounting process can be performed by instructing skip of syringe 32, and the like. Mounting control device 29 waits for a skip instruction to be received from an operator (S260), and when the skip instruction is received, mounting control device 29 registers the skip of bent syringe 32 (S265) and ends the syringe bending determination processing.

In a production process of FIG. 5, when the syringe bending determination processing is performed in this way or it is determined in S100 that it is not a timing when head 30 is powered up, mounting control device 29 waits for production preparation to be completed (S110). For example, mounting control device 29 waits for preparation to be completed, for example, a feeder of a necessary component type is set, necessary suction nozzle 31 is attached to syringe 32, and the like. When it is determined that the production preparation has been completed, mounting control device 29 carries board S by board conveyance device 22 (S115) and determines whether there is syringe 32 for which skip has been registered in the syringe bending determination processing (S120).

When it is determined that there is no syringe 32 for which skip has been registered, mounting control device 29 performs a mounting process by using suction nozzle 31 of each syringe 32 (S125). That is, the mounting process is performed such that suction nozzle 31 attached to each syringe 32 picks up a component and mounts the component on board S. Meanwhile, when it is determined that there is syringe 32 for which skip has been registered, mounting control device 29 performs the mounting process by using suction nozzle 31 of syringe 32 other than syringe 32 for which skip has been registered (S130). That is, the mounting process is performed such that a component is picked up by suction nozzle 31 attached to syringe 32 having no bending and mounted on board S except for syringe 32 having bending.

Then, mounting control device 29 waits for completion of the mounting of all components on board S (S135), and when the mounting of all components has been completed, board S is carried out by board conveyance device 22 (S140). Next, mounting control device 29 updates counter C by incrementing counter C indicating the number of produced boards S by 1 (S145) and determines whether counter C reaches predetermined value Cref (predetermined number) (S150). Predetermined value Cref is a value for determining a determination timing when the syringe bending determination processing is performed during the production process by the number of boards S to be produced and may be set by an operator through operation panel 28.

When it is determined that counter C reaches predetermined value Cref, mounting control device 29 performs the syringe bending determination processing (S155), resets counter C to a value 0 (S160), and proceeds to S165. The syringe bending determination processing in S155 is performed in the same manner as in S105 (FIG. 6) except that syringe 32 for which skip has been already registered is not included in a determination target, and thus, description thereof will be omitted. When it is determined that counter C does not reach predetermined value Cref, mounting control device 29 skips S155 and S160 and proceeds to S160. Then, mounting control device 29 determines whether the production of all boards S scheduled to be produced has been completed (S160), and when it is determined that the production of all boards S has not been completed, mounting control device 29 returns to S115 and performs the processing. When it is determined that the production of all boards S has been completed, mounting control device 29 ends the production process.

Here, a correspondence relationship between elements of the present embodiment and elements of the present disclosure will be clarified. Part camera 26 of the present embodiment corresponds to a camera, head 30 corresponds to a head, mounting control device 29 that performs S200 to S210 of syringe bending determination processing corresponds to a control section, and mounting control device 29 that performs S225 to S240 of the same process corresponds to a determination section. Further, mounting control device 29 that performs S260 of the same process and operation panel 28 correspond to a reception section. In the present embodiment, an example of a bending determination method of the present disclosure is also clarified by describing an operation of mounting device 20.

In mounting device 20 described above, in a state where syringe 32 to which jig nozzle 36 is attached is lowered at a central position of part camera 26, an image is captured from below by part camera 26, and bending of syringe 32 is determined based on the central position of jig nozzle 36 with respect to a central position of the captured image. Accordingly, the bending of syringe 32 can be determined without waiting for an inspection result or the like of the mounted component. Further, by using jig nozzle 36, the bending of syringe 32 can be appropriately determined by excluding influence of the bending of suction nozzle 31.

Further, since mounting control device 29 determines that syringe 32 is bent when distance A between a central position of an image and a central position of jig nozzle 36 is greater than or equal to a threshold (predetermined distance), it is possible to appropriately determine bending of syringe 32 while suppressing a processing load.

Further, since mounting control device 29 performs syringe bending determination processing at a timing when head 30 is attached to mounting device 20 (X-axis slider 23a), it is possible to appropriately determine bending of syringe 32 occurring before start of production due to maintenance of head 30 or the like. Accordingly, it is possible to prevent mounting accuracy of components from being reduced and a component mounting failure from occurring due to influence of bending of syringe 32 occurring before start of production.

Further, mounting control device 29 performs the syringe bending determination processing at a timing when counter C indicating a production quantity of boards S reaches predetermined value Cref. Further, since counter C is reset to a value 0 when the syringe bending determination processing is performed, the syringe bending determination processing can be performed every time the production quantity reaches predetermined value Cref. Thereby, it is possible to appropriately determine bending of syringe 32 due to collision with board S or collision with a foreign matter on board S during production. Accordingly, it is possible to prevent component mounting accuracy from being reduced or a component mounting failure from occurring due to influence of bending of syringe 32 occurring during production.

Further, since mounting control device 29 receives an instruction to skip bent syringe 32 and registers the skip, even when any syringe 32 is bent, production can be continuously performed while preventing influence on mounting accuracy. That is, it is possible to prevent production from being interrupted due to bending of syringe 32.

It is needless to say that the present disclosure is not limited in any way to the above-described embodiments, and the present disclosure can be embodied in various aspects as long as the aspects fall within the technical scope of the present disclosure.

In an embodiment, head 30 includes multiple syringes 32, and skip of bent syringe 32 can be registered, however the configuration is not limited to this. For example, a production process may be performed after replacing head 30 or replacing bent syringe 32 with another syringe 32. Further, head 30 is not limited to a rotary head and may include, for example, multiple syringes 32 arranged in parallel or may include only one syringe 32.

In an embodiment, a determination timing before start of production is set to a timing when head 30 is attached to mounting device 20 and is powered up, however the configuration is not limited to this. For example, the determination timing may be a timing when production starts regardless of whether head 30 is attached. Further, the determination timing during production is set to a timing when the number of produced boards S (counter C) reaches a predetermined value, however the configuration is not limited to this, and the determination may be made based on the number of mounted components, such as a timing when the number of mounted components reaches the predetermined value. Alternatively, the determination timing may be set to a timing when a production time after start of production by mounting device 20 reaches a predetermined time or may be set to a timing of separation of production such as switching of a board type. Further, a timing when an instruction to perform bending determination processing is received from an operator may be set as the determination timing.

In an embodiment, both before start of production (S100 in FIG. 5) and during production (S150 in FIG. 5) are exemplified as the determination timing, however the configuration is not limited to this, and the determination timing may be either before the start of production or during the production. Further, a timing when a predetermined period (a predetermined number of days, a predetermined time, or the like) elapses from the previous bending determination processing may be set as the determination timing regardless of before the start of production or during the production.

In an embodiment, bending of syringe 32 is determined at four angles as multiple determination angles, however the configuration is not limited to this, and bending may be determined at five or more angles, or two or three angles. Alternatively, the bending determination is not limited to multiple determination angles and may be made based on one determination angle, for example, a reference angle) (0°). Further, even when the determination is made at one determination angle, a target position needs only be corrected by correction values ΔX and ΔY of the angle. Further, although correction values ΔX and ΔY are reflected in the target position, correction values ΔX and ΔY need not be reflected. However, in order to appropriately determine bending of syringe 32, correction values ΔX and ΔY are preferably reflected.

In an embodiment, presence or absence of bending of syringe 32 is determined based on distance A, however the configuration is not limited to this, and the determination needs only be made based on a position of jig nozzle 36. For example, a region in a circular or rectangular predetermined region having a central position of an image as the center is set as an unbent region, a region outside the predetermined region may be set as a bent region in advance, and presence or absence of the bent may be determined based on which region a central position of jig nozzle 36 is in.

In an embodiment, a position of syringe 32 in the horizontal direction when an image of jig nozzle 36 is captured is set as a central position of part camera 26, however the configuration is not limited to this, and the position of syringe 32 may be a predetermined position. In such a case, the bending needs only be determined by calculating a distance between a predetermined position in an image and a central position of jig nozzle 36 instead of distance A described above.

In an embodiment, mounting control device 29 of mounting device 20 determines bending of syringe 32, however the configuration is not limited to this, and an image processing device or the like other than mounting control device 29 may determine the bending. Alternatively, an image captured by part camera 26 may be received by an external device such as management control device 42, and the image may be processed to determine bending.

Here, a mounting device of the present disclosure may be configured as follows. For example, in the mounting device of the present disclosure, the predetermined position may be a capturing central position of the camera, and the determination section may calculate a distance between a central position of the captured image and a central position of the jig nozzle and determine that the syringe is bent when the calculated distance is greater than or equal to a predetermined distance. Therefore, it is possible to appropriately determine bending of a syringe while suppressing a processing load.

In the mounting device of the present disclosure, the head may be provided such that the syringe is rotatable about an axis, the control section may control the head and the camera such that the syringe subsequently rotates at multiple determination angles about the axis, the syringe is set at a predetermined position by reflecting a position correction value of the syringe for each of the determination angles, and an image of the jig nozzle is captured from below for each of the determination angles, and the determination section may determine the bending of the syringe by processing multiple images captured at each of the determination angles. Therefore, it is possible to determine bending of a syringe more accurately.

In the mounting device of the present disclosure, the head may be configured to be detachable from the mounting device, and the determination timing may include a timing when the head is attached to the mounting device. Therefore, it is possible to appropriately determine bending of a syringe occurring before start of production such as maintenance of a head.

In the mounting device of the present disclosure, the determination timing may include a timing when the number of mounted components or the number of produced boards reaches a predetermined number. Therefore, it is possible to appropriately determine bending of a syringe occurring during production.

In the mounting device of the present disclosure, the head may include a reception section including multiple syringes and configured to receive an instruction from an operator so as to skip the syringe determined to be bent by the determination section and mount the component. Therefore, even when any of multiple syringes is bent, it is possible to continue production while preventing influence of the bending.

The gist of a bending determination method of the present disclosure for determining bending of a syringe in a mounting device for mounting a component on a board by picking up the component by using a suction nozzle attached to the syringe, includes
(a) a step of attaching a jig nozzle to the syringe at a predetermined determination timing,
(b) a step of capturing an image of the jig nozzle from below in a state where the syringe is lowered at a predetermined position in a horizontal direction, and
(c) a step of processing the captured image and determining the bending of the syringe based on a position of the jig nozzle with respect to the predetermined position.

A bending determination method of the present disclosure can appropriately determine bending of a syringe in the same manner as the above-described mounting device. In the bending determination method, various aspects of the above-described mounting device may be adopted, or a step of achieving each function of the above-described mounting device may be added.

### INDUSTRIAL APPLICABILITY

The present disclosure can be used in a technical field or the like of a mounting process of components.

### REFERENCE SIGNS LIST

10 mounting system, 12 print device, 14 print inspection device, 16 mounting inspection device, 18 LAN, 20 mounting device, 21 component supply device, 22 board conveyance device, 23 movement device, 23a X-axis slider, 23b Y-axis slider, 25 mark camera, 26 part camera, 27 nozzle station, 28 operation panel, 29 mounting control device, 30 head, 31 suction nozzle, 32 syringe, 33 R-axis motor, 34 Q-axis motor, 35 Z-axis motor, 36 jig nozzle, 37 base end section, 38 front end section, 38a first cylindrical section, 38b second cylindrical section, 39 flange section, 40 management device, 42 management control device, 44 input device, 46 display, 48 storage device, S board

1. A mounting device for picking up a component by a suction nozzle attached to a syringe and mounts the component on a board, the mounting device comprising:
a camera configured to capture an image of a target object from below;
a head provided with the syringe to be able to be lifted or lowered and configured to move in a horizontal direction;
a control section configured to control the head and the camera such that a jig nozzle is attached to the syringe at a predetermined determination timing and an image of the jig nozzle is captured from below in a state where the syringe is lowered at a predetermined position in the horizontal direction; and
a determination section configured to process the captured image and determine bending of the syringe based on a position of the jig nozzle with respect to the predetermined position.

2. The mounting device according to claim 1, wherein
the predetermined position is a capturing central position of the camera, and
the determination section calculates a distance between a central position of the captured image and a central position of the jig nozzle and determines that the syringe is bent when the calculated distance is greater than or equal to a predetermined distance.

3. The mounting device according to claim 1, wherein
the head is provided such that the syringe is rotatable about an axis,
the control section controls the head and the camera such that the syringe subsequently rotates at multiple determination angles about the axis, the syringe is set at the predetermined position by reflecting a position correction value of the syringe for each of the determination angles, and the image of the jig nozzle is captured from below for each of the determination angles, and
the determination section determines the bending of the syringe by processing multiple images captured at the respective determination angles.

4. The mounting device according to claim 1, wherein
the head is configured to be detachable from the mounting device, and
the determination timing includes a timing when the head is attached to the mounting device.

5. The mounting device according to claim 1, wherein
the determination timing includes a timing when a number of mounted components or a number of produced boards reaches a predetermined number.

6. The mounting device according to claim 1, wherein
the head is provided with multiple syringes and includes a reception section configured to receive an instruction from an operator to skip the syringe determined to be bent by the determination section and mount the component.

7. A bending determination method for determining bending of a syringe in a mounting device for mounting a component on a board by picking up the component by using a suction nozzle attached to the syringe, the bending determination method comprising:
(a) a step of attaching a jig nozzle to the syringe at a predetermined determination timing;
(b) a step of capturing an image of the jig nozzle from below in a state where the syringe is lowered at a predetermined position in a horizontal direction; and
(c) a step of processing the captured image and determining the bending of the syringe based on a position of the jig nozzle with respect to the predetermined position.
